(19) United States
(12) Patent Application Publication
(10) Pub. No.: US 2026/0082879 A1
(43) Pub. Date: Mar. 19, 2026

(54) DIRECTIONAL SIDEWALL DEPOSITION USING DIRECTIONAL BEAM

(71) Applicant: TEL Manufacturing and Engineering of America, Inc., Chaska, MN (US)

(72) Inventors: Yen-Tien Lu, Albany, NY (US); Chimaobi Mbanaso, Chaska, MN (US); Eric Chih-Fang Liu, Albany, NY (US); Simon Roemig, Chaska, MN (US); Michael Ramsey, Albany, NY (US)

(21) Appl. No.: 19/283,951

(22) Filed: Jul. 29, 2025

Related U.S. Application Data
(60) Provisional application No. 63/696,274, filed on Sep. 18, 2024.

(51) Int. Cl. H01L 21/768; H01J 37/32

(52) U.S. Cl. CPC H10W 20/054; H01J 37/32449; H10W 20/077; H01J 2237/33

(57) ABSTRACT

A method of processing a substrate includes providing a substrate with a line pattern including lines extending in a longitudinal direction and exposing the line pattern to a directional beam. The directional beam has an azimuthal component substantially parallel to the longitudinal direction. Exposing the line pattern to the directional beam may concurrently deposit material on sidewall surfaces of the line pattern and etch surfaces of the line pattern with a normal component parallel to the longitudinal direction. The line pattern may have localized defects. The deposited material may mitigate pinch defects in the line pattern. The etched surfaces may mitigate bridge defects in the line pattern. A controller may be configured to cause the substrate to be processed according to the method. The controller may be included in a system further including a beam source and a substrate positioner.

### CROSS-REFERENCE TO RELATED APPLICATIONS

This application claims the benefit of U.S. Provisional Application No. 63/696,274, filed on Sep. 18, 2024, which application is hereby incorporated herein by reference in its entirety.

### TECHNICAL FIELD

The present invention relates generally to semiconductor fabrication, and, in particular embodiments, to systems and methods for mitigating defects in a line pattern using a directional beam.

### BACKGROUND

The formation of microscale and nanoscale structures within a workpiece, such as within an integrated circuit (e.g., semiconductor fabrication), involves a series of processing techniques that include forming, patterning, and removing various layers of material on a substrate. Lithography processes enable the transfer of patterns onto a substrate, and include photolithography processes that use structured actinic radiation (e.g., light of a specific wavelength or narrow range of wavelengths) to pattern a layer of photosensitive material (photoresist) on the substrate. During the exposure process, the actinic radiation causes a change in the chemical structure of the photoresist that makes it more susceptible (positive tone) or less susceptible (negative tone) to being removed during a subsequent development process. When the exposed photoresist layer is developed, desired regions of the photoresist are removed leaving the pattern behind on the substrate.

The various types of photolithography can be categorized by the wavelength of the actinic radiation as well as other attributes of the exposure process, such as the medium through which the radiation propagates (gas, liquid, vacuum, etc.), the numerical aperture of the lens, and others. Among other things, these attributes affect the resolution capabilities of the photolithography process. For example, ultraviolet (UV) lithography processes, such as i-line lithography, use wavelengths in the ultraviolet range (e.g., 365 nm), deep ultraviolet (DUV) lithography processes use wavelengths in the range of about 190 nm to about 250 nm, while extreme ultraviolet (EUV) lithography processes use even shorter wavelengths, such as 13.5 nm wavelength. As the wavelength decreases, the achievable feature size also decreases (i.e., improved resolution).

The patterned layers formed by lithography processes have varying amounts of deviation in the size and shape of the formed features from the desired pattern, which may be referred to as pattern defects. Defects may be more difficult to minimize as the feature size decreases. Additionally, defects may have a more negative impact on smaller feature sizes as the difference between the desired critical dimension (CD) and the resulting CD may be a larger percentage of the CD. There are many types of defects, and defects may occur both globally (i.e., more or less consistently across the entire substrate) or for varying degrees of locality. After the patterned layer is formed, the patterned layer may be etched in an attempt to reduce pattern defects. However, conventional etching techniques fail to adequately address the various types of defects, especially local defects at smaller feature sizes. Therefore, systems and methods improved systems and methods for reducing pattern defects in a patterned layer are desirable.

### SUMMARY

In an embodiment of the invention, a method of processing a substrate includes providing a substrate that includes a line pattern with lines extending in a longitudinal direction. The method further includes exposing the line pattern to a directional beam with an azimuthal component substantially parallel to the longitudinal direction.

In another embodiment of the invention, a plasma processing controller includes a processor and a non-transitory computer-readable medium storing a program including instructions that, when executed by the processor, cause a substrate to be processed by exposing a line pattern of a substrate to a directional beam, and using the directional beam to concurrently deposit and etch. The line pattern includes lines extending in a longitudinal direction. The directional beam includes an azimuthal component substantially parallel to the longitudinal direction. The directional beam concurrently deposits material on sidewall surfaces of the line pattern and etches surfaces of the line pattern with a normal component parallel to the longitudinal direction.

In still another embodiment of the invention, a directional beam system includes a directional beam source configured to generate a directional beam, a substrate positioner configured to position a substrate relative to the directional beam, and a controller configured to cause the substrate to be processed using the directional beam. The substrate includes a line pattern with lines extending in a longitudinal direction. The directional beam has an azimuthal component substantially parallel to the longitudinal direction and is localized in both the longitudinal direction and a lateral direction. The substrate is processed using the directional beam by scanning the directional beam over the line pattern of the substrate. The directional beam concurrently deposits material on sidewall surfaces of the line pattern and etches surfaces of the line pattern with a normal component parallel to the longitudinal direction.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example process of exposing a line pattern to a directional beam that may be used to mitigate localized pattern defects, the line pattern having lines extending in a longitudinal direction and the directional beam including an azimuthal component substantially parallel to the longitudinal direction where the line pattern includes a pinch defect in accordance with embodiments of the invention;

FIG. 2 schematically illustrates an example process of exposing a line pattern to a directional beam that may be used to mitigate localized pattern defects, the line pattern having lines extending in a longitudinal direction and the directional beam including an azimuthal component substantially parallel to the longitudinal direction where the line pattern includes both a pinch defect and a bridge defect in accordance with embodiments of the invention;

FIG. 3 schematically illustrates a side view of an example process of exposing a line pattern to a directional beam that may be used to mitigate localized pattern defects, the line pattern having lines extending in a longitudinal direction viewed from a lateral direction perpendicular to the longitudinal direction and the directional beam being used to etch a bridge defect in accordance with embodiments of the invention;

FIG. 4 schematically illustrates a side view of an example process of exposing a line pattern to a directional beam that may be used to mitigate localized pattern defects, the line pattern having lines extending in a longitudinal direction viewed from the longitudinal direction and the directional beam being used to deposit material on a pinch defect in accordance with embodiments of the invention;

FIG. 5 schematically illustrates two side views of an example process of exposing a line pattern to a directional beam that may be used to mitigate localized pattern defects, the line pattern having lines extending in a longitudinal direction viewed from both the longitudinal direction and a lateral direction perpendicular to the longitudinal direction in accordance with embodiments of the invention;

FIG. 6 schematically illustrates a three-dimensional trimetric view of an example process of exposing a line pattern to a directional beam that may be used to mitigate localized pattern defects, the line pattern having lines extending in a longitudinal direction and the directional beam including an azimuthal component substantially parallel to the longitudinal direction in accordance with embodiments of the invention;

FIG. 7 schematically illustrates an example directional beam system that includes a processing chamber within which a line pattern having lines extending in a longitudinal direction on a substrate may have localized pattern defects that may be mitigated using a directional beam that includes an azimuthal component substantially parallel to the longitudinal direction in accordance with embodiments of the invention; and

FIG. 8 illustrates an example method of processing a substrate in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Conventional pattern defect reduction techniques, such as conventional etching processes are unable to adequately reduce pattern defects in a patterned layer, especially local defects at smaller feature sizes. For example, a given patterned layer may simultaneously include defects where there is too little material (e.g., features or regions of features are too small or missing) as well as defects where there is too much material (e.g., features or regions of features are too large or excess material remains in unwanted locations in the patterned layer). Conventional etch techniques are unable to etch away the unwanted excess material from the patterned layer without worsening defects related to not having enough material.

One type of defect in the specific context of line patterns is a pinch defect, which is a local narrowing of the line CD. Pinch defects are problematic as extreme cases lead to line breaks. Further processing, such as etching, can also lead to line breaks at pinch defects of the line pattern. Another type of defect is a bridge defect, which occurs when undesired material bridges the space between adjacent lines of the line pattern. Conventional dry etching processes have been used to remove bridge defects in line patterns. However, the conventional dry etching processes etch all exposed surfaces of the line pattern at a similar rate, resulting in narrowing of the line CD while the bridge defects are removed. For this reason, conventional bridge defect removal techniques that use dry etching also have the undesirable effect of worsening pinch defects, leading to line breaks and/or regions where the lines are too thin to perform an intended function, such as functioning as a hard mask.

The inventors have observed that material may be directionally deposited during processing of a line pattern using a directional beam (such as a gas cluster beam) on surfaces with a normal direction substantially perpendicular to the beam direction. For example, a directional beam with a component along the direction of propagation for lines of a line pattern (i.e., the longitudinal direction) may be used to deposit material on sidewalls of the line pattern (i.e., deposition in the lateral direction). That is, the material accumulates in the lateral direction, which is perpendicular to the propagation of the lines. In some cases, the inventors have also observed that the same directional beam can also be used directionally etch the material along the direction of the beam.

In various embodiments, material is directionally deposited using the directional beam (e.g., to mitigate pattern defects, such as line pattern defects, such as by leveraging the orthogonality of the pattern and contained defects). In some embodiments, local defects such as pinch defects, may be mitigated by directional depositing material using the directional beam. In some embodiments, global defects, such as LER, may be mitigated using the directional deposition. In various embodiments, material may be directionally etched simultaneously with and substantially perpendicular to the directional deposition. In some embodiments, local defect such as bridge defects may be mitigated by directionally etching material using the directional beam. In some embodiments, global defects, such as LER, may be also be mitigated using the directional etching, including simultaneously with LER mitigation with directional deposition.

Various gas chemistries may be used, one example of which is a carbon-containing gas chemistry (e.g. CF₄, but may also be other carbon-containing gases). A patterned layer containing the line pattern may then be formed from a material a certain related material, which in this case may also contain carbon, such as spin-on carbon (SOC). Of course, in the specific example of carbon-containing gas chemistry, other gas chemistries may be used, such as one or more fluorocarbon gases, hydrofluorocarbon gases, etc. Similarly, the material of the line pattern may also be various varieties of carbon-containing material.

The processes of mitigating pattern defects may have various advantages over conventional methods. In particular, the described processes may advantageously directionally add material (i.e., directional deposition) using a directional beam, such as a gas cluster beam (GCB), providing the benefit of being able to mitigate both global and local narrowing effects, such as pinch defects in a line pattern. A further advantage of the described processes may be to simultaneously mitigate defects where adding or preserving material is desirable (e.g., pinch defects) along with defects where removing material is desirable (e.g., bridge defects). Global defects, such as line edge roughness (LER) may also be advantageously improved by the described processes, whether by depositing material or etching away material.

The described processes may also have the advantage of selectively depositing and/or etching material, such as by tuning parameters such as beam chemistry (e.g., gas selection), energy (e.g., voltage), and tilt angle. Further, other aspects of the directional beam, such as etch/deposition ratio and rates, may also be tightly controlled over wide operating range. The described processes may also be easily adapted to current process flows by incorporating a directional beam exposure after a plasma etch. Specifically, in some embodiments, the technique of using a tilting directional beam process may be performed in addition to a plasma etch.

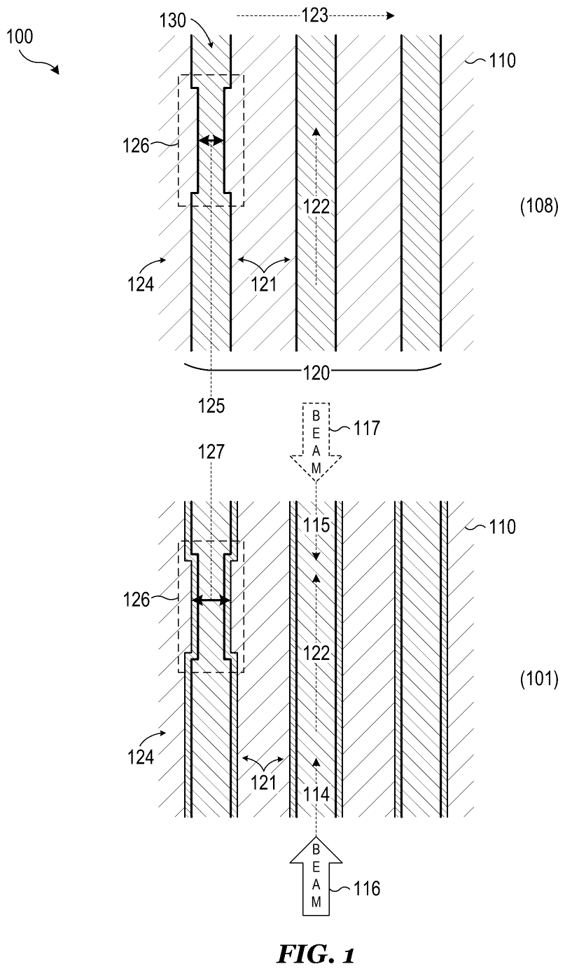

FIG. 1 schematically illustrates an example process of exposing a line pattern to a directional beam that may be used to mitigate localized pattern defects, the line pattern having lines extending in a longitudinal direction and the directional beam, (e.g., a GCB) including an azimuthal component substantially parallel to the longitudinal direction where the line pattern includes a pinch defect in accordance with embodiments of the invention.

Referring to FIG. 1, a process 100 of exposing a line pattern to a directional beam that may be used to mitigate localized pattern defects in a line pattern 120 begins with a substrate 110 in an initial state 108 where the line pattern 120 has been formed in a patterned layer 130 on an underlying layer 124 of the substrate 110. The line pattern 120 includes one or more pinch defects which are local narrowing of lines of the line pattern. For illustrative purposes, a single pinch defect 126 is shown with a pinch width 125, but of course many more pinch defects may be present in the line pattern 120 on the substrate 110. The lines of the line pattern 120 extend in a longitudinal direction 122 that is parallel to a lateral direction 123. Sidewalls 121 of the lines have a normal direction parallel to the lateral direction 123.

The substrate 110 may be any suitable substrate including or supporting the underlying layer 124, which also may be any suitable material. The patterned layer 130 may be formed from any suitable material from which a line pattern with the desired characteristics of a given application can be formed, such as a material that can function as a hard mask in a semiconductor manufacturing application. The patterned layer 130 may also include one or more material layers. In various embodiments, the patterned layer is formed from a carbon-based material (e.g., an organic material). In one embodiment, the patterned layer 130 includes a silicon-containing material. In another embodiment, the patterned layer 130 includes a metal-containing material.

When the patterned layer is formed from a carbon-based material, the carbon-based material may be an organic planarization layer (OPL), amorphous carbon layer (ACL), diamond-like carbon (DLC), spin-on carbon (SOC), an organic photoresist (PR) material, an advanced patterning film (APF), such as a carbon-rich, silicon-containing organic material, an ashable hard mask (AHM), a carbon-doped oxide (CDO), and others.

It should be noted that these categories may overlap; the patterned layer 130 may include both silicon and metal, the patterned layer 130 may include both an organic material and silicon, etc. Of course, the specific material of the patterned layer may be selected based on various factors, such as desired etch selectivity, thermal stability, ease of deposition or removal, compatibility with other materials and processes used in the semiconductor device fabrication, among other factors, some of which may be application-specific.

In a directional beam deposition step 101, the line pattern 120 of the substrate 110 is exposed to a directional beam 116 that has beam direction with an azimuthal component 114 substantially parallel to the longitudinal direction 122. That is, the directional beam 116 may have any desirable tilt angle with the substrate in addition to the azimuthal component 114. In various embodiments, the line pattern 120 is also exposed to a directional beam in the opposite azimuthal direction, such as with an optional additional directional beam 117 that has an additional azimuthal component 115 substantially parallel to the longitudinal direction and opposite the azimuthal component 114. During the directional beam deposition step 101, material is deposited on the sidewalls 121 of the line pattern 120, resulting in an increased width 127 of the pinch defect 126 (mitigating the undesirably narrow pinch width 125).

The directional beam 116 may be any suitable type of directional beam, and is formed using one or more gases containing carbon in various embodiments. For example, the directional beam 116, may be an ion beam, an electron beam, a radical beam, a neutral beam, an ion implantation beam, a GCB, such as a gas cluster ion beam (GCIB), and others. In some embodiments, the directional beam 116 is a combination of two or more beam types. Various beam optics may be used to shape and direct the directional beam 116. In some embodiments, the line pattern 120 may be simultaneously exposed to more than one directional beam 116, such as to increase throughput, for example.

The deposition of material may occur directly from species in the directional beam 116 or indirectly. For example, a beam (such as an electron beam) may provide energy or otherwise encourage deposition of gas species located in a processing chamber. In various embodiments, the directional beam 116 is a GCB that includes deposition species. In some embodiments, the deposition species are carbon-containing species, such as fluorocarbons, hydrofluorocarbons, etc.

In one embodiment, the deposition species include CF₄. In one embodiment, the deposition species include CH₃F. The deposition species may also include other species, such as C₄F₈, CH₂F₂, and others. The deposition species may also include more than one species, such as more than one carbon-containing species. For example, the deposition species may include both CF₄ and CH₃F, both CF₄ and C₄F₈, etc. In some embodiments, the deposition species may not include carbon. For example, the deposition species may be O₂ in some embodiments. In one embodiment, the directional beam 116 is formed using O₂ as the single gas species.

Other gas species may also be included in addition to the deposition species (e.g., gas species with other roles). For example, some gas species may be considered active species while some gas species may be considered carrier species, although the designation may be somewhat blurred in some cases. In some embodiments, O₂ is included in the gas species. In one embodiment, the gas species include CF₄ and O₂. In other embodiments, N₂ is included in the gas species. In one embodiment, the gas species include CF₄ and N₂. In various embodiments, the gas species include CH₃F and N₂ and the gas species include CF₄, CH₃F, and N₂ in one embodiment. In other embodiments, the gas species include C₄F₈ and N₂ (and CH₄ may or may not also be included). In still other embodiments, the gas species include CH₂F₂ and N₂ (where again CH₄ may or may not be included).

The directional beam 116 may be formed in any suitable manner, including by forming a plasma as a source of beam species that are passed (e.g., accelerated) through one or more openings, such as a slit, orifice, and the like. In various embodiments, the directional beam 116 comprises radicals generated in a plasma. In one embodiment, the plasma radicals comprise fluorine radicals.

In the specific example where the directional beam 116 is implemented as a GCB, a source gas may be processed to form gas clusters (e.g., gas clusters may be formed by condensation induced by adiabatic expansion of compressed gas into a vacuum). The gas clusters may be ionized to produce ions, such as through collisions with energetic electrons. The ionized clusters may be accelerated by a voltage differential towards the substrate 110. The gas clusters may have any desired mixture of species, including ions, neutrals, radicals, plasma effluents, and others. In various embodiments, the directional beam 116 may be considered a gas cluster ion beam (GCIB), although even in this case the ratio of ions to other species may be relatively small. In some embodiments, such as when a few or no ions are desired, the directional beam 116 may be neutralized after the gas clusters are accelerated. Upon reaching surfaces of the substrate 110, the gas clusters may interact with the materials (e.g., including one or both physical and chemical interactions). For example, at impact, the clusters may disintegrate and deliver kinetic energy that may promote formation of deposited material and/or dislodge regions of the excess material.

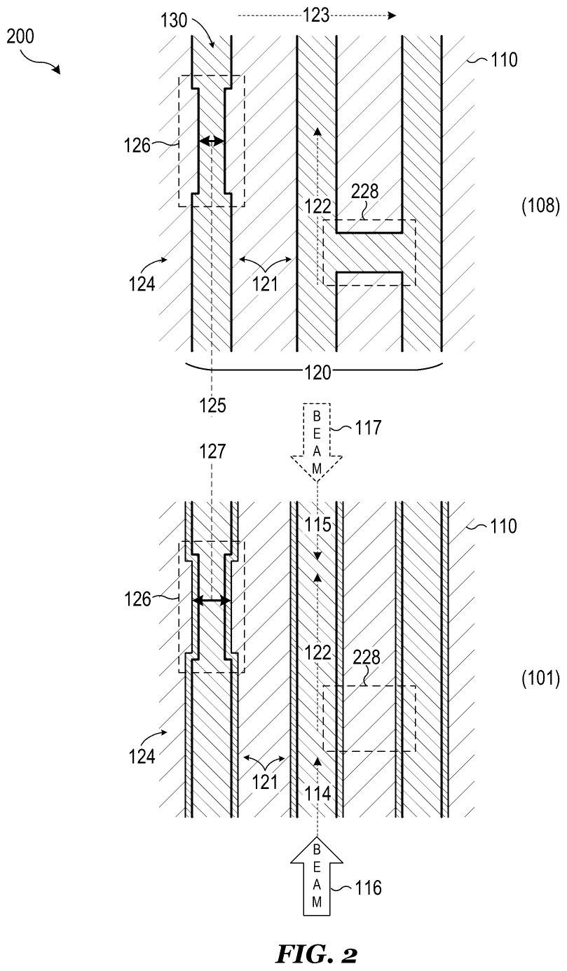

FIG. 2 schematically illustrates an example process of exposing a line pattern to a directional beam that may be used to mitigate localized pattern defects, the line pattern having lines extending in a longitudinal direction and the directional beam including an azimuthal component substantially parallel to the longitudinal direction where the line pattern includes both a pinch defect and a bridge defect in accordance with embodiments of the invention. The process of FIG. 2 may be a specific implementation of other processes described herein such as the process of FIG. 1, for example. Similarly labeled elements may be as previously described.

Referring to FIG. 2, a process 200 is similar to the process 100 except that in this specific example, the line pattern 120 includes a bridge defect 228 in addition to a pinch defect 126. As before, only a single bridge defect 228 is shown for illustrative purposes, but many bridge defects may be present in various locations of the line pattern in practice. The bridge defect 228 partially or completely bridges across a gap in the line pattern 120 in the lateral direction 123. In this specific example, during the directional beam deposition step 101, the bridge defect 228 is removed (i.e., directionally etched) simultaneously with the material directionally deposited on the sidewalls 121 using the same directional beam 116 (and the additional directional beam 117, when included).

The mechanism of removing the bridge defect 228 may be related to the azimuthal component of the directional beam 116 being in the longitudinal direction 122. For example, the kinetic energy of the directional beam 116 in the longitudinal direction 122 may provide reaction energy for chemical reactions with the material of the bridge defect 228. Additionally or alternatively, the gas cluster species may physically dislodge material from surfaces of the bridge defect 228 that are at least partially facing the longitudinal direction 122 (i.e. have a normal component parallel with the longitudinal direction 122). Advantageously, the directional beam 116 may remove less or no material from surfaces of the pattern of lines 120 that do not face the directional beam 116 (e.g., sidewalls of the pattern of lines 120). For example, material may instead be deposited on the sidewalls 121 of the line pattern 120.

In one embodiment, the directional beam 116 includes CF₄. In one embodiment, the directional beam 116 includes CH₃F. The directional beam 116 may also include other species, such as C₄F₈, CH₂F₂, and others. More than one species may be included in the directional beam 116. For example, the directional beam 116 may include both CF₄ and CH₃F, both CF₄ and C₄F₈, and others. In some embodiments, the directional beam 116 may not include carbon. For example, the deposition species may be O₂ in some embodiments. In one embodiment, the directional beam 116 is formed using O₂ as the single gas species.

Other gas species may also be included in addition to the directional beam 116 (e.g., gas species with other roles). For example, some gas species may be considered active species while some gas species may be considered carrier species. Carrier species may be configured to perform non-reactive roles (such as building pressure in a nozzle used to generate the directional beam 116, for example). In some embodiments, O₂ is included in the gas species. In other embodiments, N₂ is included in the gas species. For example, N₂ may be included as a carrier species in some cases. The designation between active species and carrier species may be somewhat blurred in some cases. For example, O₂ may be included as both an active species and a carrier species.

In one embodiment, t the directional beam 116 includes CF₄ and O₂. In one embodiment, the directional beam 116 includes CF₄ and N₂. In various embodiments, the directional beam 116 includes CH₃F and N₂ and the directional beam 116 includes CF₄, CH₃F, and N₂ in one embodiment. In other embodiments, the directional beam 116 includes C₄F₈ and N₂ (and CH₄ may or may not also be included). In still other embodiments, the directional beam 116 includes CH₂F₂ and N₂ (where again CH₄ may or may not be included).

The chemistry of the directional beam 116 used directionally etch the bridge defect 228 may be influenced by various factors, including the material of the line pattern 120. In various embodiments, a halogen may be included in the chemistry of the directional beam 116. In some embodiments, the halogen includes chlorine and includes Cl₂ in one embodiment. In another embodiment the halogen includes fluorine and is F₂ in one embodiment. In some embodiments, the halogen includes a halogenated compound, such as CₓF_{y} compounds, CₓH_{y}F_{z} compounds, NF₃, SiCl₄, SFₓ, HBr, BCl₃, and others.

For example, a halogen may be used to etch silicon-containing and/or metal-containing materials of the line pattern 120. In one embodiment, the directional beam 116 includes a halogen and the line pattern 120 includes elemental silicon (Si). In various embodiments, the directional beam 116 includes a halogen and the line pattern 120 includes a metal-containing material, such as titanium nitride (TiN) in one embodiment, elemental tungsten (W) in another embodiment, a tungsten oxide material (WOₓ) in some embodiments, and tin oxide (SnO₂) in one embodiment.

The directional beam 116 may be adjusted before, after, or during the process 200 of exposing a line pattern to a directional beam that may be used to mitigate the localized pattern defects in the line pattern 120. For example, the directional beam 116 may adjusted to modify a ratio of deposited material to etched material. The ratio of deposited material to etched material may refer to the amount of deposited material on the sidewalls 121 of the line pattern 120 relative to the amount of material etched from surfaces of the line pattern facing the directional beam 116 (like the bridge defect 228). Another ratio of deposited material to etched material compares deposition and etching on surfaces facing the same direction, such as the ratio of deposition to etching on sidewalls or the ratio of deposition to etching on surfaces facing the directional beam 116.

In one embodiment, adjusting the directional beam 116 includes increasing the beam energy of the directional beam 116 to increase the etch rate in the longitudinal direction thereby decreasing the ratio of deposited material to etched material. In another embodiment, adjusting the directional beam 116 includes increasing the tilt angle of the directional beam 116 relative to a normal direction of the substrate to increase the etch rate in the longitudinal direction thereby decreasing the ratio of deposited material to etched material. In some cases, some material may be deposited by the directional beam 116 on upper surfaces of the line pattern 120 and exposed surfaces of substrate 110. Adjusting the tilt angle of the directional beam 116 may also influence how much material is deposited on upper surfaces.

The chemistry of the directional beam may also be adjusted. In one embodiment, adjusting the directional beam 116 includes increasing a concentration of polymerizing compounds in a source gas used to form the directional beam 116 to increase the deposition rate of material on the sidewalls 121 in a lateral direction perpendicular to the longitudinal direction thereby increasing the ratio of deposited material to etched material.

In one embodiment, the deposition and etching of surfaces of the sidewalls 121 is substantially balanced. The surfaces of the sidewalls 121 may have a substantially perpendicular facing relative to the direction of the directional beam 116 (i.e., have a normal direction substantially perpendicular to the longitudinal direction). For example, this may allow material to be both deposited and smoothed (via directional etching) further reducing or eliminating the effects of pinch and bulge defects over time.

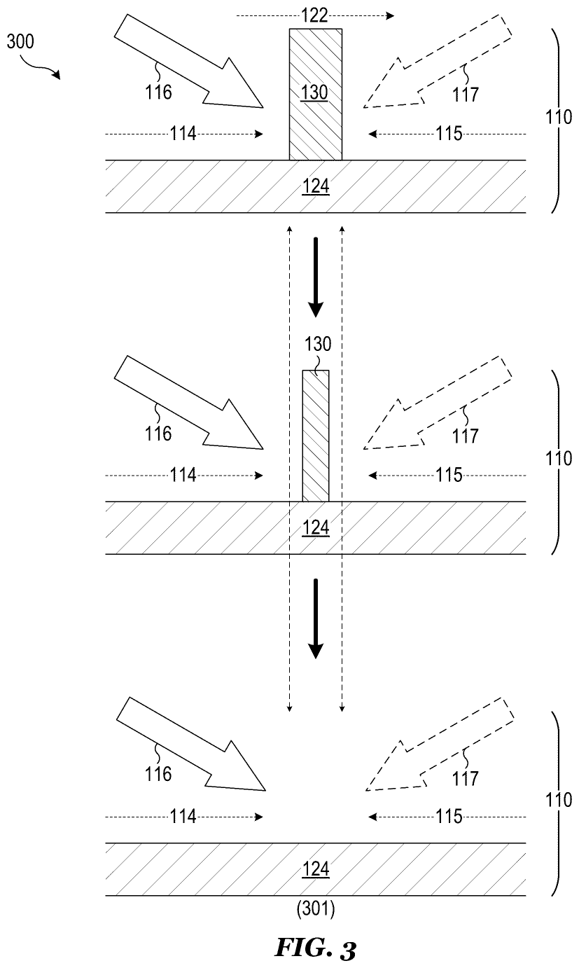

FIG. 3 schematically illustrates a side view of an example process of exposing a line pattern to a directional beam that may be used to mitigate localized pattern defects, the line pattern having lines extending in a longitudinal direction viewed from a lateral direction perpendicular to the longitudinal direction and the directional beam being used to etch a bridge defect in accordance with embodiments of the invention. The process of FIG. 3 may be a specific implementation of other processes described herein such as the process of FIG. 1, for example. Similarly labeled elements may be as previously described.

Referring to FIG. 3, a process 300 (which may be similar to the process 100) shows a side view from a lateral direction perpendicular to the longitudinal direction 122 of the directional beam directional deposition step where the patterned layer 130 is also directionally etched using the directional beam 116 (and the optional additional directional beam 117, when included).

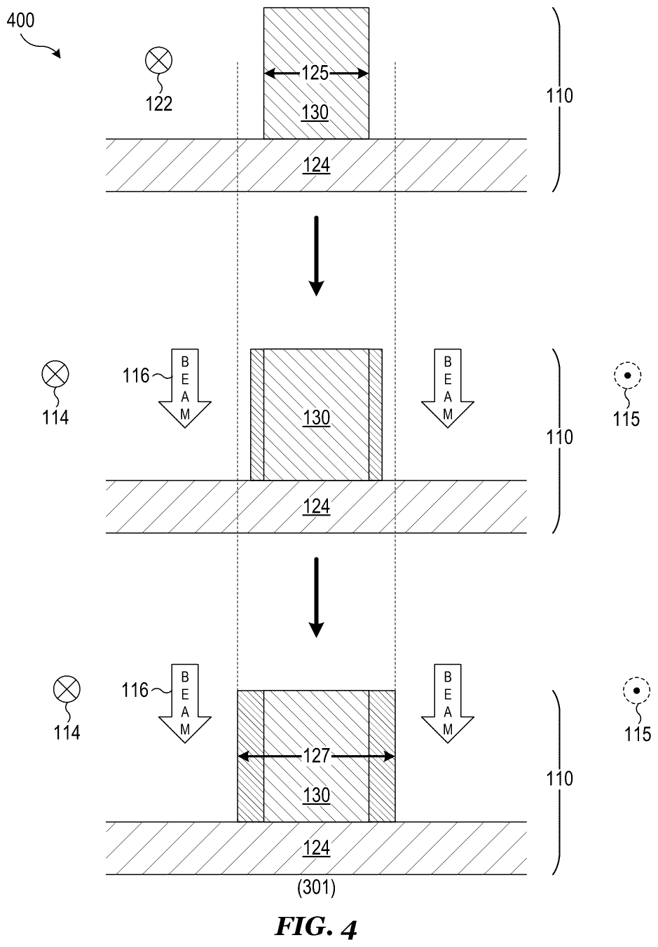

FIG. 4 schematically illustrates a side view of an example process of exposing a line pattern to a directional beam that may be used to mitigate localized pattern defects, the line pattern having lines extending in a longitudinal direction viewed from the longitudinal direction and the directional beam being used to deposit material on a pinch defect in accordance with embodiments of the invention. The process of FIG. 4 may be a specific implementation of other processes described herein such as the process of FIG. 1, for example. Similarly labeled elements may be as previously described.

Referring to FIG. 4, a process 400 (which may be similar to the process 100) shows a side view from the longitudinal direction of the directional beam deposition step where material is directionally deposited on the patterned layer 130 using the directional beam 116. In this view, the azimuthal component 114 is directed into the page while the additional azimuthal component 115 is directed out of the page (when the optional additional directional beam is included).

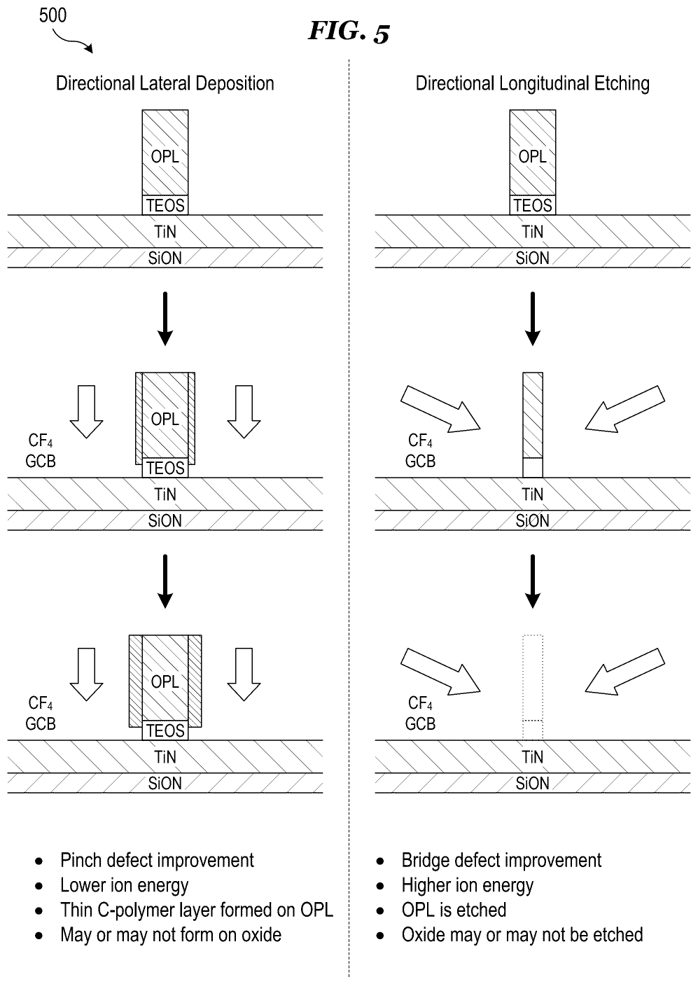

FIG. 5 schematically illustrates two side views of an example process of exposing a line pattern to a directional beam that may be used to mitigate localized pattern defects, the line pattern having lines extending in a longitudinal direction viewed from both the longitudinal direction and a lateral direction perpendicular to the longitudinal direction in accordance with embodiments of the invention. The process of FIG. 5 may be a specific implementation of other processes described herein such as the process of FIG. 1, for example. Similarly labeled elements may be as previously described.

Referring to FIG. 5, a process 500 shows a specific example of the previously described processes from two side views where the underlying layer of the substrate is titanium nitride (TiN) on silicon oxynitride (SiON) and the patterned layer is formed from an organic planarization layer (OPL) on an oxide layer, which here is tetraethyl orthosilicate (TEOS). A directional beam including tetrafluoromethane gas (CF₄) is used to selectively deposit a carbon-containing polymer on sidewalls of the OPL in the lateral direction while the OPL and TEOS is simultaneously and selectively etched in the longitudinal direction.

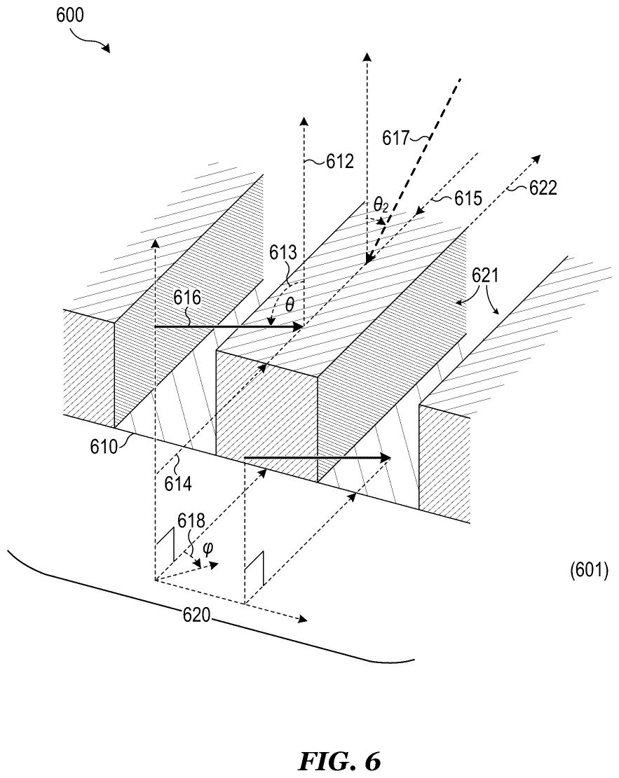

FIG. 6 schematically illustrates a three-dimensional trimetric view of an example process of exposing a line pattern to a directional beam that may be used to mitigate localized pattern defects, the line pattern having lines extending in a longitudinal direction and the directional beam including an azimuthal component substantially parallel to the longitudinal direction in accordance with embodiments of the invention. The process of FIG. 6 may be a specific implementation of other processes described herein such as the process of FIG. 1, for example. Similarly labeled elements may be as previously described.

Referring to FIG. 6, a process 600, which may be similar to any of the previously described processes, is shown during a directional beam deposition step 601 where a directional beam 616 is applied to a pattern of lines 620 formed on a substrate 610. As shown, the directional beam 616 is applied with an azimuthal component 614 that is substantially parallel to a longitudinal direction 622 of sidewalls 621 of the pattern of lines 620. If the azimuthal component 614 were not substantially parallel, an azimuthal angle 618 would be nonzero, which may be undesirable because the directionality of the deposition and etching effects of may be reduced or applied in the wrong direction. The directional beam 616 is also applied with a tilt angle 613 relative to a normal direction 612 of the substrate 610, which may be selected as any desired angle greater than zero up to and including 90 degrees. As before, an optional additional directional beam 617 with an additional azimuthal component 615 may also be applied in some embodiments.

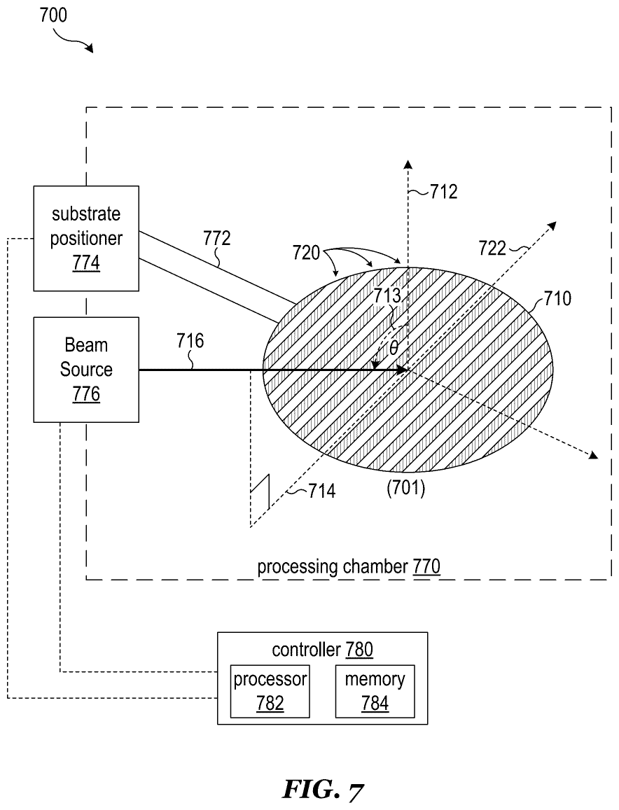

FIG. 7 schematically illustrates an example directional beam system that includes a processing chamber within which a line pattern having lines extending in a longitudinal direction on a substrate may have localized pattern defects that may be mitigated using a directional beam that includes an azimuthal component substantially parallel to the longitudinal direction in accordance with embodiments of the invention. The directional beam system of FIG. 7 may be used to perform processes and methods described herein such as the process of FIG. 1, for example. Similarly labeled elements may be as previously described.

Referring to FIG. 7, a directional beam system 700 is shown during a directional beam directional deposition 701. The directional beam system 700 includes a processing chamber 770 within which a directional beam source 776 is used to apply a directional beam 716 to a line pattern 720 formed on a substrate 710 and extending in a longitudinal direction 722. The directional beam 716 is applied at a tilt angle 713 relative to a normal direction 712 of the substrate 710 and with an azimuthal component 714 substantially parallel to the longitudinal direction 722. Although the directional beam 716 may be applied to the entire substrate 710 in some embodiments, in this specific example a substrate support 772 is mechanically coupled to a substrate positioner 774 that is used to manipulate the position of the substrate 710 allowing the desired tilt angle 713 to be maintained and the substrate 710 to be moved to scan the directional beam 716 over the desired regions of the substrate 710 (e.g., in a raster pattern).

A controller 780 is operatively coupled to the various components of the directional beam system 700, including the substrate positioner 774 and the directional beam source 776. The controller 780 includes one or more processors 782 and at least one memory 784 (i.e., a non-transitory computer-readable medium) that stores a program including instructions that, when executed by the one or more processors 782, perform the defect mitigation steps described herein.

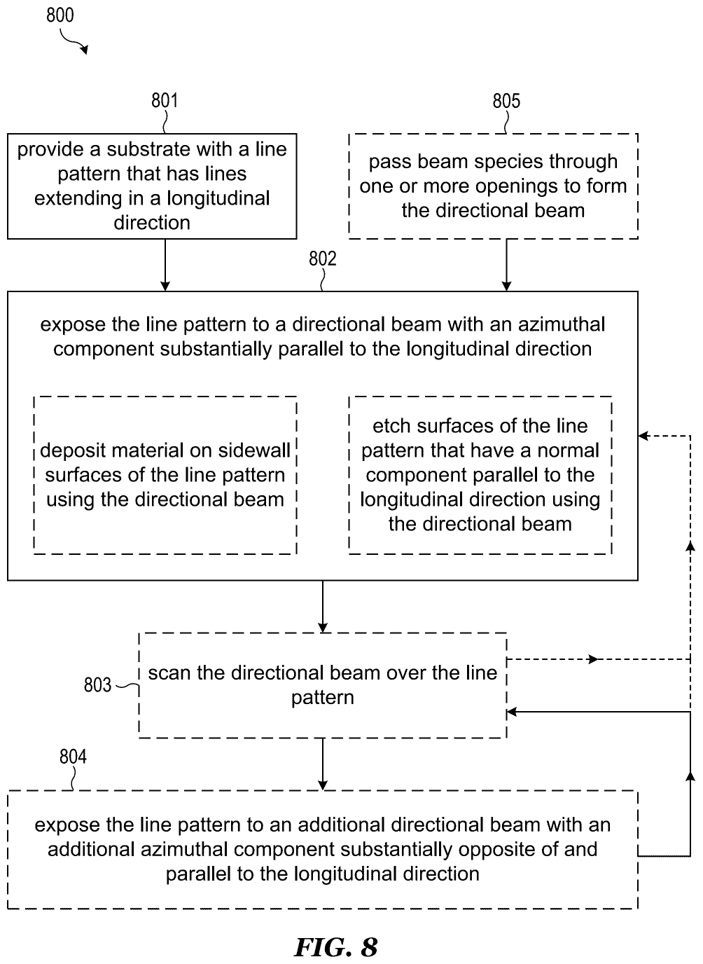

FIG. 8 illustrates an example method of processing a substrate in accordance with embodiments of the invention. The method of FIG. 8 may be performed using the systems and apparatuses as described herein. For example, the method of FIG. 8 may be combined with any of the embodiments of FIGS. 1-7. The method steps of FIG. 8 may be performed in any suitable order or concurrently with one another as may be apparent to a person of skill in the art.

Referring to FIG. 8, a method 800 of processing a substrate includes providing a substrate with a line pattern (box 801). The line pattern has lines extending in a longitudinal direction. That is, the lines of the line pattern may be straight and parallel to one another, each extending in the longitudinal direction (the lines being conceptualized as two-dimensional, though they have some nonzero height and width). The substrate has at least one line pattern, and may have more than one line pattern. In some cases, the substrate may have more than one line pattern with different corresponding longitudinal directions.

The line pattern is exposed to a directional beam with an azimuthal component substantially parallel to the longitudinal direction (box 802). The exposure to the directional beam may mitigate localized pattern defects in the line pattern. Specifically, the line pattern may include pinch defects, bridge defects, or a combination thereof (in addition to other defects, such as LER). For example, the pinch defects may locally narrow the line CD of the lines. The bridge defects may have material extending between adjacent lines of the line pattern (i.e., bridge regions). Some or all of the defects may be mitigated by the directional beam, including the pinch defects, the bridge defects, and other defects (e.g., smoothing the LER of the sidewalls by removing rough regions using the directional beam).

In some embodiments, the directional beam is used to deposit material on sidewall surfaces of the line pattern, which may mitigate pinch defects. The directional beam may include deposition species that interact with the material of the line pattern to deposit the material on the sidewall surfaces. The material may deposit substantially evenly on surfaces parallel or nearly parallel to the sidewalls of the line pattern so that the line CD of the line pattern increases globally. In some cases, the material may deposit preferentially in some regions of the sidewall. One example may be preferential deposition at pinch defects where irregularities in the flatness of the sidewalls allows more material to be deposited. The directional beam parameters (e.g., beam species, beam energy, angle of incidence, dose, dwell time, etc.) may be selected so that any increase in line CD is sufficiently small to avoid adversely affecting the line pattern itself.

In some embodiments, the directional beam is used to etch surfaces of the line pattern that have a normal component parallel to the longitudinal direction (i.e., facing the directional beam), which may mitigate bridge defects. The directional beam may include one or more varieties of beam species, including species functioning as etch species. In various embodiments, the beam species include radicals, and the beam species include fluorine radicals in some embodiments.

Multiple localized line defects may be concurrently mitigated by the same directional beam. In one embodiment, the line pattern includes both pinch defects and bridge defects and the exposure to the directional beam deposits material on sidewalls to mitigate the pinch defects and etches surfaces facing the beam to mitigate the bridge defects. The effect of the directional beam on surfaces of the line pattern may depend on the direction the surface is facing relative to the directional beam (i.e., relative to the longitudinal direction). For example, the surfaces of the line pattern with a normal component parallel to the longitudinal direction but normal to the orientation of the defects may be etched, causing a preferential etching mode to occur due to the directionality.

When multiple line defects are concurrently mitigated using the same directional beam, such as when both pinch defects and bridge defects are present, exposing the line pattern to the directional beam may include substantially balancing deposition and etching of sidewall surfaces of the lines of the line pattern. For example, pinch defects may include transition regions where the angle of incidence of the directional beam is lower (allowing more kinetic energy to be transferred to the surface). These regions may be etched, locally decreasing the line CD while the deposition locally and/or globally increases the line CD. It may be desirable to balance these effects so that the pinch defects are mitigated while the line CD is substantially unaffected or at least minimally affected.

The directional beam may be adjusted in one or more ways, both dynamically or in between exposures of the same or different line patterns. In one embodiment, the directional beam is adjusted to modify a ratio of deposited material to etched material while exposing the line pattern to the directional beam. In another embodiment, the directional beam is adjusted by increasing beam energy of the directional beam. For example, increased beam energy may increase the etch rate in the longitudinal direction thereby decreasing the ratio of deposited material to etched material.

In still another embodiment the directional beam is adjusted by increasing a tilt angle of the directional beam relative to a normal direction of the substrate. This may increase the etch rate in the longitudinal direction thereby decreasing the ratio of deposited material to etched material. In various embodiments, the directional beam has a tilt angle greater than about 30 degrees relative to a normal surface of the substrate. Although any tilt angle is possible, smaller tilt angles may have the undesirable effect of etching upper surfaces of the line pattern and/or the substrate. The tilt angle may be large, such as greater than about 45 degrees in some embodiments. In one embodiment, the tilt angle is greater than about 60 degrees. Of course, tilt angles up to an including 90 degrees are possible, depending on the specific details of the beam source, substrate, and the line pattern.

In yet another embodiment, the directional beam is adjusted by increasing a concentration of polymerizing compounds in a source gas used to form the directional beam. Increasing the concentration of polymerizing compounds may increase the deposition rate of material on sidewalls of the line pattern in a lateral direction perpendicular to the longitudinal direction thereby increasing the ratio of deposited material to etched material.

For example, sidewall surfaces may have substantially no normal component parallel to the longitudinal direction so that beam species do not impact the sidewalls or impact at very high (e.g., substantially 90 degree) angles of incidence, which may deposit material, such as through chemical reactions between the beam species and the material of the line pattern. By comparison, surfaces that have a normal component facing the longitudinal direction may be impacted by beam species at lower angles of incidence which may etch the material of the surfaces, such as by physically dislodging material.

The directional beam may be focused on a localized region of the substrate. That is, the directional beam may be conceptually understood to be spot (e.g., a localized 2D spot in the plane of the (wafer) substrate), being bound in both the longitudinal direction and the perpendicular lateral direction in the plane of the substrate. The spot size of the directional beam may be any desired size, though smaller spot sizes may have the advantage of affording more localized control over defect mitigation.

The directional beam may be scanned over the line pattern (box 803) over the desired region of the line pattern (and/or the substrate), which may locally mitigate defects. For example, the directional beam may be scanned over a wafer substrate (e.g., the entire wafer substrate) in a raster pattern (or any other desired pattern for the matter, such as a spiral pattern, a circular pattern, etc.). The scanning may be implemented in any suitable way, such as moving the substrate relative to the beam source, moving the beam source relative to the substrate, or a combination thereof.

In some embodiments, only a portion of the substrate is scanned, such as when the line pattern only covers some of the substrate. In one embodiment, additional line patterns are exposed to the directional beam, such as at other portions of the substrate. The line patterns may be oriented in a different direction (i.e., have different corresponding longitudinal directions), and the substrate (or the beam source) may be reoriented (i.e., rotated) to align the directional beam with the longitudinal direction of the respective line pattern before exposure.

It may also be desirable to expose the line pattern to an additional directional beam with an additional azimuthal component substantially opposite of and parallel to the longitudinal direction, such as to further mitigate the localized pattern defects (box 804). That is, the line pattern may be exposed to the directional beam with a component both in the longitudinal direction and opposite (but parallel to) the longitudinal direction. This may be desirable, for example, to improve mitigation of bridge defects and LER smoothing. In some cases, the line pattern may be exposed to the directional beam more than two times, such as alternating between the two directions.

In one example, the far side of each pinch defect may be etched while material is globally deposited on the sidewalls. The directional beam may then be applied in the opposite longitudinal direction, etching the other side of each pinch defect while material is globally deposited. By selecting the beam parameters to balance these effects, the pinch defects may be smoothed (locally broadened) while the global line CD remains substantially constant or minimally increased.

The directional beam may be any suitable beam or combination of beams. In some embodiments, the directional beam may be formed by passing beam species though one or more openings (box 805), such as a nozzle to create an adiabatic expansion of the beam species and form a GCB (gas cluster beam). In some embodiments, the GCB includes ions, and the GCB includes ions in a ratio of less than about 1 ion to about 1000 neutral species in one embodiment. In some cases implementations of the directional beam as a GCB that includes ions may be considered a GCIB.

In various embodiments, the directional beam is formed from one or more gases including a halogen. In one embodiment, the halogen includes chlorine. In one embodiment, the halogen includes fluorine. The halogen may be included as part of a chemical compound (more than one type of element), or as an elemental form of the halogen, such as Cl₂, for example.

In some embodiments, the directional beam is formed from one or more gases including carbon. For example, the one or more gases may include a fluorocarbon gas having a chemical formula of the form CₓF_{z}. In one embodiment, x=1 and z=4 so that the fluorocarbon gas includes tetrafluoromethane (CF₄) gas. The one or more gases may also include a hydrofluorocarbon gas having a chemical formula of the form CₓH_{y}F_{z}. In some embodiments, x=1, y is in the range of 1 to 4, and z=4-y so that the hydrofluorocarbon gas has the chemical formula CH_{y}F_{4-y}.

The one or more gases used to form the directional beam may be a mixture of gases. The mixture of gases may include various species including species that include a halogen, species that include carbon, and others. In various embodiments, the one or more gases are a mixture of gases including multiple gases that each include carbon. In some embodiments, the mixture of gases include a fluorocarbon gas and a hydrofluorocarbon gas. In one embodiment, the mixture of gases includes a carbon-less gas (e.g., in addition to carbon-containing gases or without any carbon-containing gases). Examples of a carbon-less gas that may be included in the mixture of gases are gases that include oxygen. In one embodiment, the carbon-less gas is diatomic oxygen (O₂).

In order to impart directionality to the directional beam, beam species may be charged (e.g., stripped of electrons to ionize beam species). In one embodiment, the directional beam is neutralized before reaching the line pattern. It should be noted that this neutralization may be at a beam level so that the directional beam may still include some number of charged species, but the net charge of the beam itself approaches zero.

The directional beam may be or include other types of directional beams as well. In one embodiment, the directional beam includes an ion beam. In another embodiment, the directional beam includes an electron beam. In still another embodiment, the directional beam includes a neutral beam (i.e., a beam of neutral particles with net velocity). In yet another embodiment, the directional beam includes a radical beam. In still yet another embodiment, the directional beam includes an ion implantation beam, which may include any type of ion beam, such as conventional ion beams, monomer ion beams, and cluster ion beams.

The directional nature of the directional beam means that the beam species have a net kinetic energy in a certain direction (although there may be beam spread due to beam species interactions or thermal motion). That is, the energy of at least some of the beam species is greater in the longitudinal direction than in a lateral direction perpendicular to the longitudinal direction in the plane of the substrate. In one embodiment, the directional beam has higher ion energy in the longitudinal direction and lower ion energy in the lateral direction.

The line pattern may be formed in any suitable way and include any desired material or combination of materials or material layers. In one embodiment, the line patter is formed using an extreme ultraviolet (EUV) lithography process. In one embodiment, the line pattern includes a photoresist material. The line pattern may include an organic material. In some embodiments, the line pattern includes a hardmask. In one embodiment, the line pattern includes an organic hardmask. The line pattern includes a carbon-containing material, such as spin-on-carbon (SOC), in some embodiments. In one embodiment, the line pattern is formed by etching a carbon-containing layer. The etched carbon-containing layer may represent be the only layer of the line pattern or may be one of multiple layers, all of which may or may not contain carbon.

In some embodiments, the line pattern includes a silicon-containing material, and the line pattern includes elemental silicon (Si) in one embodiment. In various embodiments, the line pattern includes a metal-containing material. In one embodiment, the metal containing material includes titanium. In another embodiment, the metal-containing material includes tungsten. In still another embodiment, the metal-containing material includes tin.

The method 800 may be performed using any of the apparatuses and system described herein. For example, a controller may include a processor and a non-transitory computer-readable medium storing a program including instructions that, when executed by the processor, cause a substrate to be processed according to the method 800. A directional beam system may also be configured to perform the method 800. For example, the directional beam system may include a directional beam source configured to generate a directional beam and a substrate positioner configured to position a substrate relative to the directional beam. The directional beam system may further include a controller configured to cause the substrate to be processed using the directional beam according to the method 800.

Example embodiments of the invention are summarized here. Other embodiments can also be understood from the entirety of the specification as well as the claims filed herein.

Example 1. A method of processing a substrate, the method including: providing a substrate including a line pattern including lines extending in a longitudinal direction; and exposing the line pattern to a directional beam including an azimuthal component substantially parallel to the longitudinal direction. The lines pattern may have localized pattern defects that are mitigated by exposing the line pattern to the directional beam.

Example 2. The method of example 1, where exposing the line pattern to the directional beam includes concurrently depositing material on sidewall surfaces of the line pattern using the directional beam, and etching surfaces of the line pattern having a normal component parallel to the longitudinal direction using the directional beam.

Example 3. The method of one of examples 1 and 2, where the line pattern includes localized pattern defects that include a pinch defect in sidewall surfaces of a line of the line pattern, the pinch defect locally narrowing a line critical dimension (CD) of the line; and where exposing the line pattern to the directional beam includes depositing material on the pinch defect of the sidewall surfaces using the directional beam.

Example 4. The method of example 3, where the directional beam includes a gas cluster beam (GCB) including deposition species.

Example 5. The method of one of examples 3 and 4, where the directional beam has higher ion energy in the longitudinal direction and lower ion energy in a lateral direction perpendicular to the longitudinal direction.

Example 6. The method of one of examples 3 to 5, where the depositing the material globally increases the line CD of the line pattern.

Example 7. The method of one of examples 3 to 6, where the line pattern includes localized pattern defects that further include a bridge defect between adjacent lines, the bridge defect including a bridge region of material extending between adjacent lines of the line pattern; and where exposing the line pattern to the directional beam includes locally etching surfaces of the bridge region in the longitudinal direction using the directional beam concurrently with depositing the material on the pinch defect of the sidewall surfaces.

Example 8. The method of example 7, where exposing the line pattern to the directional beam includes substantially balancing deposition and etching of sidewall surfaces of the lines of the line pattern, the sidewall surfaces including a normal direction substantially perpendicular to the longitudinal direction.

Example 9. The method of one of examples 7 and 8, further including: adjusting the directional beam to modify a ratio of deposited material to etched material while exposing the line pattern to the directional beam.

Example 10. The method of example 9, where adjusting the directional beam includes increasing beam energy of the directional beam to increase the etch rate in the longitudinal direction thereby decreasing the ratio of deposited material to etched material.

Example 11. The method of one of examples 9 and 10, where adjusting the directional beam includes increasing a tilt angle of the directional beam relative to a normal direction of the substrate to increase the etch rate in the longitudinal direction thereby decreasing the ratio of deposited material to etched material.

Example 12. The method of one of examples 9 to 11, where adjusting the directional beam includes increasing a concentration of polymerizing compounds in a source gas used to form the directional beam to increase the deposition rate of material on sidewalls of the line pattern in a lateral direction perpendicular to the longitudinal direction thereby increasing the ratio of deposited material to etched material.

Example 13. The method of one of examples 1 to 6, where the line pattern includes localized pattern defects that include a bridge defect between adjacent lines, the bridge defect including a bridge region of material extending between adjacent lines of the line pattern; and where exposing the line pattern to the directional beam includes locally etching surfaces of the bridge region in the longitudinal direction using the directional beam.

Example 14. The method of one of examples 1 to 13, where the line pattern further includes line edge roughness (LER) on sidewalls of the line pattern, and where exposing the line pattern to the directional beam includes smoothing the LER of the sidewalls by removing rough regions from the sidewalls using the directional beam.

Example 15. The method of one of examples 1 to 14, further including: passing beam species through one or more openings to form the directional beam.

Example 16. The method of example 15, where the beam species include radicals.

Example 17. The method of example 16, where the radicals include fluorine radicals.

Example 18. The method of one of examples 1 to 17, where the directional beam includes a gas cluster beam (GCB).

Example 19. The method of example 18, where the gas cluster beam includes ions in a ratio of less than about 1 ion to about 1000 neutral species.

Example 20. The method of one of examples 18 and 19, where the gas cluster beam is neutralized before reaching the line pattern.

Example 21. The method of one of examples 18 to 20, where the gas cluster beam includes a gas cluster ion beam (GCIB).

Example 22. The method of one of examples 1 to 21, where the directional beam includes an ion beam.

Example 23. The method of one of examples 1 to 22, where the directional beam includes an electron beam.

Example 24. The method of one of examples 1 to 23, where the directional beam includes a neutral beam.

Example 25. The method of one of examples 1 to 24, where the directional beam includes a radical beam.

Example 26. The method of one of examples 1 to 25, where the directional beam includes an ion implantation beam.

Example 27. The method of one of examples 1 to 26, further including: plasma etching a carbon-containing layer to form the line pattern.

Example 28. The method of one of examples 1 to 27, further including: forming the directional beam from one or more gases including a halogen.

Example 29. The method of example 28, where the halogen includes chlorine.

Example 30. The method of one of examples 28 and 29, where the halogen includes fluorine.

Example 31. The method of one of examples 28 to 30, where the line pattern includes a silicon-containing material.

Example 32. The method of example 31, where the line pattern includes elemental silicon (Si).

Example 33. The method of one of examples 28 to 32, where the line pattern includes a metal-containing material.

Example 34. The method of example 33, where the line pattern includes titanium.

Example 35. The method of one of examples 33 and 34, where the line pattern includes tungsten.

Example 36. The method of one of examples 33 to 35, where the line pattern includes tin.

Example 37. The method of one of examples 1 to 36, further including: forming the directional beam from one or more gases including carbon.

Example 38. The method of example 37, where the one or more gases include a fluorocarbon gas having a chemical formula CₓF_{z}.

Example 39. The method of example 38, where the fluorocarbon gas includes tetrafluoromethane (CF₄) gas.

Example 40. The method of one of examples 37 to 39, where the one or more gases include a hydrofluorocarbon gas having a chemical formula CₓH_{y}F_{z}.

Example 41. The method of example 40, where the chemical formula is CH_{y}F_{4-y}, and where y is in the range from 1 to 4.

Example 42. The method of one of examples 37 to 41, where the one or more gases include a mixture of gases.

Example 43. The method of example 42, where the mixture of gases includes a plurality of gases, each including carbon.

Example 44. The method of example 43, where the mixture of gases includes a fluorocarbon gas and a hydrofluorocarbon gas.

Example 45. The method of one of examples 42 to 44, where the mixture of gases includes a carbon-less gas.

Example 46. The method of example 45, where the carbon-less gas includes oxygen gas.

Example 47. The method of example 46, where the oxygen gas is diatomic oxygen (O₂).

Example 48. The method of one of examples 1 to 47, where the line pattern includes a hard mask.

Example 49. The method of example 48, where the hard mask is an organic hard mask.

Example 50. The method of one of examples 1 to 49, where the line pattern includes a carbon-containing material.

Example 51. The method of example 50, where the carbon-containing material includes spin-on carbon (SOC).

Example 52. The method of one of examples 1 to 51, where the directional beam has a tilt angle greater than about 30 degrees relative to a normal surface of the substrate.

Example 53. The method of example 52, where the tilt angle is greater than about 45 degrees.

Example 54. The method of example 53, where the tilt angle is greater than about 60 degrees.

Example 55. The method of one of examples 1 to 54, where the line pattern is formed using an EUV lithography process.

Example 56. The method of one of examples 1 to 55, where the line pattern includes a photoresist material.

Example 57. The method of one of examples 1 to 56, where the line pattern includes an organic material.

Example 58. The method of one of examples 1 to 57, further including: exposing the line pattern to an additional directional beam including an additional azimuthal component substantially opposite of and parallel to the longitudinal direction. For example, the additional directional beam may further mitigate localized pattern defects.

Example 59. The method of one of examples 1 to 58, where the substrate is a wafer substrate, and where exposing the line pattern to the directional beam includes scanning the directional beam over the wafer substrate in a raster pattern.

Example 60. The method of one of examples 1 to 59, wherein the directional beam is formed from gas species comprising carbon-containing species and one or more carrier species selected from the group consisting of dioxygen gas (O₂) and dinitrogen gas (N₂).

Example 61. The method of example 60, wherein the carbon-containing species comprise tetrafluoromethane gas (CF₄).

Example 62. The method of one of examples 1 to 16, wherein the directional beam is formed from a single gas species, the single gas species being dioxygen gas (O₂).

Example 63. A plasma processing controller including a processor and a non-transitory computer-readable medium storing a program including instructions that, when executed by the processor, cause a substrate to be processed by: exposing a line pattern of a substrate to a directional beam, the line pattern including lines extending in a longitudinal direction, the directional beam including an azimuthal component substantially parallel to the longitudinal direction; and using the directional beam to concurrently deposit material on sidewall surfaces of the line pattern and etch surfaces of the line pattern having a normal component parallel to the longitudinal direction. The line pattern may have localized pattern defects that are mitigated by concurrently depositing and etching using the directional beam.

Example 64. The plasma processing controller of example 63, where the line pattern includes localized pattern defects that include a pinch defect in the sidewall surfaces locally narrowing a line critical dimension (CD) of a line of the line pattern; and where depositing the material on the sidewall surfaces includes depositing material on the pinch defect.

Example 65. The plasma processing controller of one of examples 63 and 64, where the line pattern includes localized pattern defects that include a bridge defect between adjacent lines of the line pattern, the bridge defect including a bridge region of material extending between adjacent lines of the line pattern; and where etching the surfaces includes locally etching the bridge region in the longitudinal direction.

Example 66. The plasma processing controller of one of examples 63 to 65, where the program includes further instructions that, when executed by the processor, cause the directional beam to be adjusted to modify a ratio of deposited material to etched material by: increasing beam energy of the directional beam to increase the etch rate in the longitudinal direction thereby decreasing the ratio of deposited material to etched material; increasing a tilt angle of the directional beam relative to a normal direction of the substrate to increase the etch rate in the longitudinal direction thereby decreasing the ratio of deposited material to etched material; or increasing a concentration of polymerizing compounds in a source gas used to form the directional beam to increase the deposition rate of material on sidewalls of the line pattern in a lateral direction perpendicular to the longitudinal direction thereby increasing the ratio of deposited material to etched material.

Example 67. A directional beam system including: a directional beam source configured to generate a directional beam including an azimuthal component substantially parallel to a longitudinal direction; a substrate positioner configured to position a substrate relative to the directional beam, the substrate including a line pattern including lines extending in the longitudinal direction, the directional beam being localized in both the longitudinal direction and a lateral direction; and a controller configured to cause the substrate to be processed using the directional beam by scanning the directional beam over the line pattern of the substrate, and using the directional beam to concurrently deposit material on sidewall surfaces of the line pattern and etch surfaces of the line pattern having a normal component parallel to the longitudinal direction. The line pattern may have localized pattern defects that are mitigated by concurrently depositing and etching using the directional beam.

Example 68. The directional beam system of example 67, where the line pattern includes localized pattern defects that include a pinch defect in the sidewall surfaces locally narrowing a line critical dimension (CD) of a line of the line pattern; and where depositing the material on the sidewall surfaces includes depositing material on the pinch defect.

Example 69. The directional beam system of one of examples 67 and 68, where the line pattern includes localized pattern defects that include a bridge defect between adjacent lines of the line pattern, the bridge defect including a bridge region of material extending between adjacent lines of the line pattern; and where etching the surfaces includes locally etching the bridge region in the longitudinal direction.

Example 70. The directional beam system of one of examples 67 to 69, where the controller is further configured to adjust the directional beam to modify a ratio of deposited material to etched material by: increasing beam energy of the directional beam to increase the etch rate in the longitudinal direction thereby decreasing the ratio of deposited material to etched material; increasing a tilt angle of the directional beam relative to a normal direction of the substrate to increase the etch rate in the longitudinal direction thereby decreasing the ratio of deposited material to etched material; or increasing a concentration of polymerizing compounds in a source gas used to form the directional beam to increase the deposition rate of material on sidewalls of the line pattern in the lateral direction perpendicular to the longitudinal direction thereby increasing the ratio of deposited material to etched material.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
providing a substrate comprising a line pattern comprising lines extending in a longitudinal direction, the line pattern; and
exposing the line pattern to a directional beam comprising an azimuthal component substantially parallel to the longitudinal direction.

2. The method of claim 1, wherein exposing the line pattern to the directional beam comprises concurrently
depositing material on sidewall surfaces of the line pattern using the directional beam, and
etching surfaces of the line pattern having a normal component parallel to the longitudinal direction using the directional beam.

3. The method of claim 1,
wherein the line pattern comprises localized pattern defects comprising a pinch defect in sidewall surfaces of a line of the line pattern, the pinch defect locally narrowing a line critical dimension (CD) of the line; and
wherein exposing the line pattern to the directional beam comprises depositing material on the pinch defect of the sidewall surfaces using the directional beam.

4. The method of claim 1, wherein the directional beam is formed from gas species comprising carbon-containing species and one or more carrier species selected from the group consisting of dioxygen gas (O₂) and dinitrogen gas (N₂).

5. The method of claim 4, wherein the carbon-containing species comprise tetrafluoromethane gas (CF₄).

6. The method of claim 1, wherein the directional beam is formed from a single gas species, the single gas species being dioxygen gas (O₂).

7. The method of claim 6, wherein exposing the line pattern to the directional beam comprises substantially balancing deposition and etching of sidewall surfaces of the lines of the line pattern, the sidewall surfaces comprising a normal direction substantially perpendicular to the longitudinal direction.

8. The method of claim 6, further comprising:
adjusting the directional beam to modify a ratio of deposited material to etched material while exposing the line pattern to the directional beam.

9. The method of claim 8, wherein adjusting the directional beam comprises increasing beam energy of the directional beam to increase the etch rate in the longitudinal direction thereby decreasing the ratio of deposited material to etched material.

10. The method of claim 8, wherein adjusting the directional beam comprises increasing a tilt angle of the directional beam relative to a normal direction of the substrate to increase the etch rate in the longitudinal direction thereby decreasing the ratio of deposited material to etched material.

11. The method of claim 8, wherein adjusting the directional beam comprises increasing a concentration of polymerizing compounds in a source gas used to form the directional beam to increase the deposition rate of material on sidewalls of the line pattern in a lateral direction perpendicular to the longitudinal direction thereby increasing the ratio of deposited material to etched material.

12. The method of claim 1,
wherein the line pattern comprises localized pattern defects comprising a bridge defect between adjacent lines, the bridge defect comprising a bridge region of material extending between adjacent lines of the line pattern; and
wherein exposing the line pattern to the directional beam comprises locally etching surfaces of the bridge region in the longitudinal direction using the directional beam.

13. A plasma processing controller comprising a processor and a non-transitory computer-readable medium storing a program including instructions that, when executed by the processor, cause a substrate to be processed by:
exposing a line pattern of a substrate to a directional beam, the line pattern comprising lines extending in a longitudinal direction, the directional beam comprising an azimuthal component substantially parallel to the longitudinal direction; and
using the directional beam to concurrently deposit material on sidewall surfaces of the line pattern and etch surfaces of the line pattern having a normal component parallel to the longitudinal direction.

14. The plasma processing controller of claim 13,
wherein the line pattern comprises localized pattern defects comprising a pinch defect in the sidewall surfaces locally narrowing a line critical dimension (CD) of a line of the line pattern; and
wherein depositing the material on the sidewall surfaces comprises depositing material on the pinch defect.

15. The plasma processing controller of claim 13,
wherein the line pattern comprises localized pattern defects comprising a bridge defect between adjacent lines of the line pattern, the bridge defect comprising a bridge region of material extending between adjacent lines of the line pattern; and
wherein etching the surfaces comprises locally etching the bridge region in the longitudinal direction.

16. The plasma processing controller of claim 13, wherein the program comprises further instructions that, when executed by the processor, cause the directional beam to be adjusted to modify a ratio of deposited material to etched material by:
increasing beam energy of the directional beam to increase the etch rate in the longitudinal direction thereby decreasing the ratio of deposited material to etched material;
increasing a tilt angle of the directional beam relative to a normal direction of the substrate to increase the etch rate in the longitudinal direction thereby decreasing the ratio of deposited material to etched material; or
increasing a concentration of polymerizing compounds in a source gas used to form the directional beam to increase the deposition rate of material on sidewalls of the line pattern in a lateral direction perpendicular to the longitudinal direction thereby increasing the ratio of deposited material to etched material.

17. A directional beam system comprising:
a directional beam source configured to generate a directional beam comprising an azimuthal component substantially parallel to a longitudinal direction;
a substrate positioner configured to position a substrate relative to the directional beam, the substrate comprising a line pattern comprising lines extending in the longitudinal direction, the directional beam being localized in both the longitudinal direction and a lateral direction; and
a controller configured to cause the substrate to be processed using the directional beam by
scanning the directional beam over the line pattern of the substrate, and
using the directional beam to concurrently deposit material on sidewall surfaces of the line pattern and etch surfaces of the line pattern having a normal component parallel to the longitudinal direction.

18. The directional beam system of claim 17,
wherein the line pattern comprises localized pattern defects comprising a pinch defect in the sidewall surfaces locally narrowing a line critical dimension (CD) of a line of the line pattern; and
wherein depositing the material on the sidewall surfaces comprises depositing material on the pinch defect.

19. The directional beam system of claim 17,
wherein the line pattern comprises localized pattern defects comprising a bridge defect between adjacent lines of the line pattern, the bridge defect comprising a bridge region of material extending between adjacent lines of the line pattern; and
wherein etching the surfaces comprises locally etching the bridge region in the longitudinal direction.

20. The directional beam system of claim 17, wherein the controller is further configured to adjust the directional beam to modify a ratio of deposited material to etched material by:
increasing beam energy of the directional beam to increase the etch rate in the longitudinal direction thereby decreasing the ratio of deposited material to etched material;
increasing a tilt angle of the directional beam relative to a normal direction of the substrate to increase the etch rate in the longitudinal direction thereby decreasing the ratio of deposited material to etched material; or
increasing a concentration of polymerizing compounds in a source gas used to form the directional beam to increase the deposition rate of material on sidewalls of the line pattern in the lateral direction perpendicular to the longitudinal direction thereby increasing the ratio of deposited material to etched material.
